(19) United States
(12) Patent Application Publication
(10) Pub. No.: US 2009/0021402 A1
(43) Pub. Date: Jan. 22, 2009

(54) INPUT DEVICE OF ELECTRONIC APPARATUS

(75) Inventors: Te-Sheng Jan, Tu-Cheng (TW); Yan-Juan Ji, Shenzhen City (CN); Shih-Tsai Liu, Tu-Cheng (TW); Ruey-Shyang You, Tu-Cheng (TW); Kenneth Zhao, Tu-Cheng (TW); Ding-Ding Zhang, Shenzhen City (CN); Kuan-Hong Hsieh, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/166,331

(22) Filed: Jul. 2, 2008

(30) Foreign Application Priority Data
Jul. 20, 2007 (CN) 200710076089.X

(51) Int. Cl. H03M 11/00

(52) U.S. Cl. 341/35

(57) ABSTRACT

An input device for an electronic apparatus includes a rotary dial module and a keypad surrounding the rotary dial module. The rotary dial module includes a base plate, a flexible printed circuit board, a retainer, a rotary dial, and a plurality of contacts. The flexible printed circuit board is mounted on the base plate. The retainer is positioned above the flexible printed circuit board and is mounted on the base plate. The rotary dial is rotatably mounted on the retainer. The contacts are mounted on the flexible printed circuit board. Each of the contacts is assigned to a portion of the rotary dial and capable of forming a closed circuit when the corresponding portion of the rotary dial is pressed down and in contact with the contact. The input device has a compact size because the rotary dial can replace some keys.

### BACKGROUND

1. Technical Field

The present invention relates to an input device of an electronic apparatus.

2. General Background

Keypads and rotary dials are common input devices for electronic apparatuses. Keypads are suitable for inputting characters. Rotary dials are more suitable in selecting menu options. Because electronic apparatuses are integrated with more and more functions such as multimedia, telephone communicating, text messaging, etc., keypads and rotary dials have been integrated as single input devices for the electronic apparatuses to input data conveniently. But in the traditional integrated input devices, keypads and rotary dials are merely positioned together and not structurally combined, thus, the integrated input devices usually have large sizes and look bulky.

Thus, what is needed is a compact-sized input device that includes structurally integrated keypad and rotary dial.

### SUMMARY

An input device for an electronic apparatus is disclosed. The input device includes a rotary dial module and a keypad surrounding the rotary dial module. The rotary dial module includes a base plate, a flexible printed circuit board, a retainer, a rotary dial, and a plurality of contacts. The flexible printed circuit board is mounted on the base plate. The retainer is positioned above the flexible printed circuit board and is mounted on the base plate. The rotary dial is rotatably mounted on the retainer. The contacts are mounted on the flexible printed circuit board. Each of the contacts is assigned to a portion of the rotary dial and capable of forming a closed circuit when the corresponding portion of the rotary dial is pressed down and in contact with the contact.

Other advantages and novel features of the present invention will become more apparent from the following detailed description of exemplary embodiments when taken in conjunction with the accompanying drawings.

### BRIEF DESCRIPTION OF THE DRAWINGS

The components of the drawings are not necessarily drawn to measuring scale, the emphasis instead being placed upon clearly illustrating the principles of the input device. Moreover, in the drawings, like reference numerals designate corresponding parts throughout the several views.

FIG. 1 is a schematic, front view of an electronic apparatus with an input device according to an exemplary embodiment of the present invention.

FIG. 2 is an exploded view of FIG. 1.

FIG. 3 is an enlarged scale sectional view of FIG. 1, taken along line I-I in FIG. 1.

### DETAILED DESCRIPTION OF THE EMBODIMENT

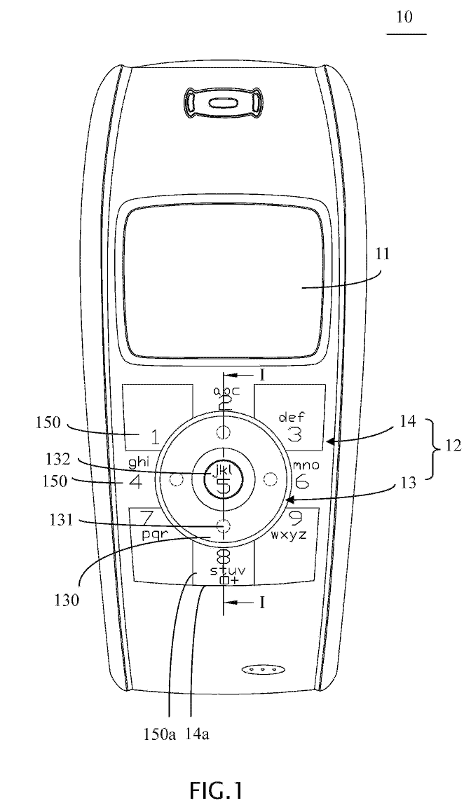

Referring to FIG. 1, a portable electronic device 10 is disclosed. The electronic device 10 includes a display 11 and an input device 12. The input device 12 includes a rotary dial module 13 and a keypad 14. The Keypad 14 surrounds the rotary dial module 13.

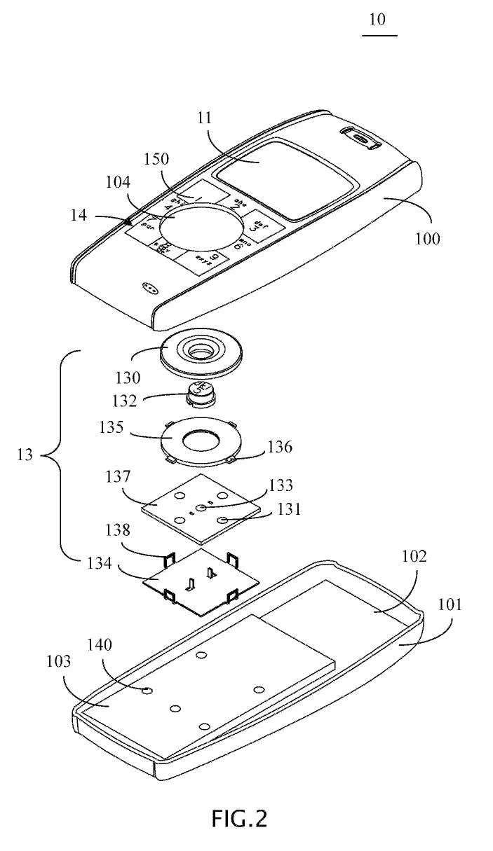

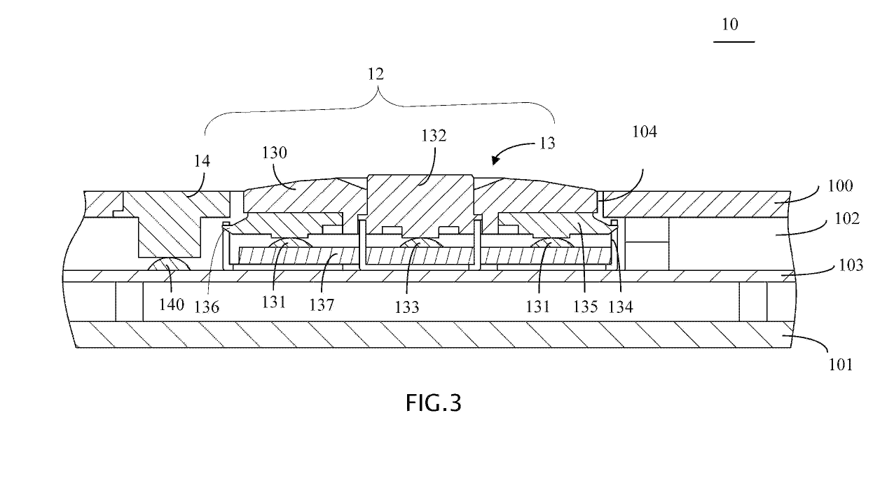

Referring to FIGS. 2 and 3, the electronic device 10 further includes an upper cover 100 and a bottom cover 101. The upper cover 100 and the bottom cover 101 cooperatively form a cavity 102. The cavity 102 receives a printed circuit board (PCB) 103.

The rotary dial module 13 includes a base plate 134, a flexible printed circuit board (FPCB) 137, an annular retainer 135, an annular rotary dial 130, and a button 132. The base plate 134 is mounted on the PCB 103. The FPCB 137 is mounted on the base plate 134. The retainer 135 is placed upon the FPCB 137. A plurality of clasps 136 that extend from an outer edge of the retainer 135 engage with corresponding clasp holders 138 that extend from the base plate 134, thus connecting the retainer 135 with the base plate 134. The rotary dial 130 is rotatably mounted on the retainer 135. The rotary dial 130 and the retainer 135 are annular and enclose the button 132. The rotary dial 130 and the button 132 pass through a hole 104 and are exposed to a user.

A first contact 133 and a plurality of second contacts 131 are mounted on the FPCB 137. The first contact 133 is placed under the button 132. The first contact 133 forms a closed circuit when the button 132 is pressed down. The second contacts 131 are placed under the rotary dial 130. One of the second contacts 131 forms a closed circuit when a corresponding portion of the rotary dial 130 is pressed down. A plurality of third contacts 140 corresponding to keys of the keypad 14 are mounted on the PCB 103 and are placed under the keypad 14. One of the third contacts 140 forms a closed circuit when a corresponding key of the keypad 14 is pressed down. A plurality of icons 150 are shown on an upper surface of the electronic device 10. Each icon 150 is assigned to a contact 131, 133, or 140 and is labeled with characters.

The rotary dial 130 can be rotated to select options of a menu, and the rotary dial 130 and the keypad 14 can be pressed down to input characters. The input method employed here can be same as an input method used in a traditional keypad.

The second contacts 131 are placed under the rotary dial 130, thus, the rotary dial 130 can replace some keys, the keypad 14 has fewer keys than a traditional keypad, and the whole input device 12 achieves compact sizes.

Moreover, it is to be understood that the invention may be embodied in other forms without departing from the spirit thereof. Thus, the present examples and embodiments are to be considered in all respects as illustrative and not restrictive, and the invention is not to be limited to the details given herein.

What is claimed is:

1. An input device for an electronic apparatus, comprising:
a rotary dial module comprising:
a base plate;
a flexible printed circuit board mounted on the base plate;
a retainer positioned above the flexible printed circuit board, wherein the retainer is mounted on the base plate;
a rotary dial rotatably mounted on the retainer; and
a plurality of contacts mounted on the flexible printed circuit board, wherein each of the contacts is assigned to a portion of the rotary dial and capable of forming a closed circuit when the corresponding portion of the rotary dial is pressed down and in contact with the contact; and
a keypad surrounding the rotary dial module.

2. The input device of claim 1, further comprising a plurality of clasps extending from an outer edge of the retainer and a plurality of clasp holders extending from the base plate, wherein each clasp engages with one of the plurality of clasp holders.

3. The input device of claim 1, wherein the rotary dial and the retainer are annular.

4. The input device of claim 3, further comprising a button enclosed by the rotary dial and retainer.

5. The input device of claim 4, further comprising icons labeled with characters, wherein the icons are assigned to the contacts, a portion of the keypad, or the button.
